(19) United States
(12) Patent Application Publication
(10) Pub. No.: US 2005/0264365 A1
(43) Pub. Date: Dec. 1, 2005

(54) Linearity enhanced amplifier

(76) Inventor: Greg Takahashi, Santa Cruz, CA (US)

Correspondence Address: DORSEY & WHITNEY LLP, 555 CALIFORNIA STREET, SUITE 1000, SUITE 1000, SAN FRANCISCO, CA, 94104, US

(21) Appl. No.: 11/140,132

(22) Filed: May 26, 2005

Related U.S. Application Data
(60) Provisional application No. 60/575,573, filed on May 28, 2004.

(51) Int. Cl. H03F 3/04

(52) U.S. Cl. 330/296; 330/288

(57) ABSTRACT

An amplifier circuit according to one embodiment of the present invention comprises an amplifier transistor configured to amplify an input signal received at a terminal of the amplifier transistor, and a bias circuit having a bias transistor forming a current mirror with the amplifier transistor for stabilizing a bias operating point for the amplifier transistor, a buffer transistor coupled to the bias transistor and to the amplifier transistor, and a current source coupled to the buffer transistor and configured to generate a temperature-dependent current for injection into the buffer transistor. The buffer transistor improves linearity of the amplifier transistor by creating a predistortion of the input signal, and the current source injects the temperature-dependent current into the buffer transistor to adjust the extent of predistortion and to compensate for undesirable effects caused by variations in ambient conditions.

### CROSS REFERENCE TO RELATED APPLICATIONS

The present application claims the benefit of and priority to U.S. Provisional patent application No. 60/575,573 entitled “Amplifier Linearity Enhancement with Temperature-Compensated Predistortion Bias Circuit,” filed on May 28, 2004, the entire disclosure of which is incorporated herein by reference.

### FIELD OF THE INVENTION

The present invention relates in general to amplifier linearity enhancement technologies, and more particularly to a linearity-enhanced amplifier with a temperature-compensated predistortion bias circuit to achieve temperature-independent linearity as well as temperature-stable amplification.

### BACKGROUND OF THE INVENTION

The performance of microwave amplifiers based on heterostructure bipolar transistors generally improves with increased collector current density up to certain optimal point determined by a number of complex effects. Due to reliability limitations, however, the collector current density at which a heterostructure bipolar transistor can be operated is often set at a value below the maximum achievable gain. In order to ensure consistent performance, it is also important that this current density be maintained during normal variations in operating conditions, and in particular over a range of ambient temperature at which the amplifier is expected to operate.

It is well-known that the collector current in a forward active region of a bipolar transistor is exponentially related to the temperature approximately as follows:
I_{C}=I_{S}e^{q}^{^{V}}^{BE}^{^{/kT}}(V_{BE}>>kT/q) (1)
where I_{c} is the collector current, I_{S} is a constant, q is the electron charge, k is Boltzmann's constant, V_{BE} is the base to emitter voltage, and T is the temperature in Kelvin. FIG. 1 illustrates a conventional amplifier circuit 100, in which a conventional resistive voltage divider 110, formed using resistors R_{b1} and R_{b2}, is used to set a DC bias at the base of bipolar transistor Q_{RF}, the collector of which is biased through a serially connected inductor L1 between a power supply V_{CC} and ground. It can be expected that, based on Eq. (1), the transistor collector current I_{c} would vary significantly as a function of temperature.

Various solutions are known in the art to stabilize the operating current of a bipolar transistor. In an amplifier circuit 200 shown in FIG. 2, a bias resistor R_{b} is added to be in series with the voltage divider 110. This improvement is simple and inexpensive, and introduces a negative DC feedback for improved bias stability over temperature. It has a disadvantage, however, because the bias resistor R_{b} dissipates significant DC power and reduces the voltage available for forming a collector bias thereby reducing power output capability of the amplifier circuit.

FIG. 3 illustrates a conventional amplifier circuit 300, which employs a current mirror arrangement to stabilize a bias operating point for the transistor Q_{RF} without the drawbacks of the series bias resistor approach in circuit 200. As shown in FIG. 3, a bias transistor Q_{b1} is introduced, which is similar to transitor Q_{RF} but with a smaller periphery. A reference current Iᵣ through the bias transistor is fixed by bias resistors R_{b1} and R_{b2}, and a controlled voltage at the base of transistor Q_{b1} provides a temperature-compensated bias voltage to the base of transistor Q_{RF} through a base resistor R_{b3}. In this fashion, the base-emitter voltage of Q_{RF} is controlled to maintain a constant collector current proportional to the reference current Iᵣ through transistor Q_{b1}.

The disadvantages of circuit 300 are two-fold. First, the resistance associated with base resistor R_{b3}, which is provided to minimize coupling of an RF input signal into the base of transistor Q_{b1}, needs to be large compared to an input impedance of transistor Q_{RF}, which is typically around 50 ohms. Thus, R_{b3} is typically on the order of a few hundred ohms. Since the base current of transistor Q_{RF} may be significantly large, a significant voltage drop occurs across resistor R_{b3}, which decouples the base-emitter DC voltage of transistor Q_{RF} from that of transistor Q_{b1}. Secondly, because the relatively large base current of transistor Q_{RF} is drawn from the reference current Iᵣ through R_{b1}, a significant mismatch between the reference current Iᵣ through R_{b1} and the collector current of transistor Q_{b1} is thus introduced. As a result, the base current through R_{b3} and the collector current through Q_{b1} would vary significantly as the current gain value β of transistor Q_{RF} changes over temperature. This in turn would result in undesirable bias current variations in Q_{RF} over temperature.

FIG. 4 illustrates a conventional amplifier circuit 400 employing an improved current mirror with a buffer transistor Q_{b2} as a current buffer. Transistor Q_{b2} provides a source for the base currents of transistors Q_{RF} and Q_{b1}, while its own base current, which comes through a resistor R_{b4}, can be small in comparison. Circuit 400 further includes a second base resistor R_{b5} serially coupled with base resistor R_{b3}. Base resistor R_{b5} can have a small resistance to avoid excessive DC voltage variations at the base of transistor Q_{RF}, while base resistor R_{b3} can remain large to isolate transistor Q_{b1} from the RF input signal. As a consequence, however, the emitter-base junction of transistor Q_{b2} is inevitably exposed to a sizable fraction of the input RF signal. Therefore, as this junction is forward-biased in normal operation, it will have a highly nonlinear capacitance and current with respect to an input voltage, resulting effectively in a nonlinear load being presented to the RF input signal, in addition to that provided by the base-emitter junction of transistor Q_{RF}. Thus, a predistortion of the input signal to transistor Q_{RF} can occur as a result.

Linearity is important in many applications, and particularly in microwave communications, where distortion or departure from linearity may lead to undesired spectral components in transmitted signals, distortion of received signals, and interference between wanted signals and unwanted blocking signals in receivers. The component of distortion of greatest interest in many applications is the so called cubic or third-order distortion, which is often characterized by measuring an output third-order intercept point OIP3, that is, the output power at which an extrapolated third-order intermodulation product is equal to a fundamental output tone. Typically, a maximum OIP3 value indicates an optimal overall linearity. By both simulation and experiment, it is found that the RF frequency at which an optimal overall linearity is obtained in the prior-art circuit 400 of FIG. 4 exhibits significant variations with temperature, as shown in FIG. 5. Such variations will result in inconsistent linearity at the frequency of operation as ambient temperature varies, which is unacceptable in many applications.

### SUMMARY OF THE INVENTION

It is an object of the invention to provide a microwave bipolar transistor amplifier with constant, well-controlled bias current, and consistently excellent linearity over a wide range of temperature, without degradation of power efficiency. It is a further object of the invention to provide means for adapting the dependency of linearity on frequency to the needs of any specific application, without requiring changes in the RF amplifier circuit configuration.

An amplifier circuit according to one embodiment of the present invention comprises an amplifier transistor configured to amplify an input signal received at a terminal of the amplifier transistor, and a bias circuit having a bias transistor forming a current mirror with the amplifier transistor for stabilizing a bias operating point for the amplifier transistor, a buffer transistor coupled to the bias transistor and to the amplifier transistor, and a current source coupled to the buffer transistor and configured to generate a temperature-dependent current for injection into the buffer transistor. The buffer transistor provides a DC base current for the amplifier transistor and improves linearity of the amplifier transistor by creating a predistortion of the input signal. The current source injects the temperature-dependent current into the buffer transistor to adjust the extent of predistortion and to compensate for effects caused by variations in ambient conditions. The behavior of the current source is designed to vary the predistortion characteristics of the bias circuit to track and cancel the distortion characteristics of the amplifier circuit over temperature, resulting in temperature-independent enhanced linearity performance of the overall amplifier circuit.

### BRIEF DESCRIPTION OF THE DRAWINGS

FIG. 1 is a circuit schematic illustrating a conventional amplifier circuit employing a resistive voltage divider for base bias.

FIG. 2 is a circuit schematic illustrating a conventional amplifier circuit having an added series bias resistor.

FIG. 3 is a circuit schematic illustrating a conventional amplifier circuit employing a current mirror bias scheme.

FIG. 4 is a circuit schematic illustrating a conventional amplifier circuit employing a current mirror with buffer transistor.

FIG. 5 is a chart showing plots of output third-order intercept point vs. frequency, at three different ambient temperatures, for the conventional amplifier circuit shown in FIG. 4.

FIG. 6 is a circuit schematic illustrating an amplifier circuit according to one embodiment of the present invention.

FIG. 7 is a circuit schematic illustrating an example of a temperature-compensating current source in the amplifier circuit shown in FIG. 6.

FIG. 8 is a circuit schematic of a PTAT (proportional-to-absolute-temperature) cell according to one embodiment of the present invention.

FIG. 9 is a chart illustrating a temperature-compensating current source output I_{TC}.

FIG. 10 is a circuit schematic of a negative temperature coefficient current source according to an alternative embodiment of the present invention.

FIG. 11 is a chart showing simulated results of OIP3 versus temperature incorporating the temperature-compensating current source according to one embodiment of the present invention.

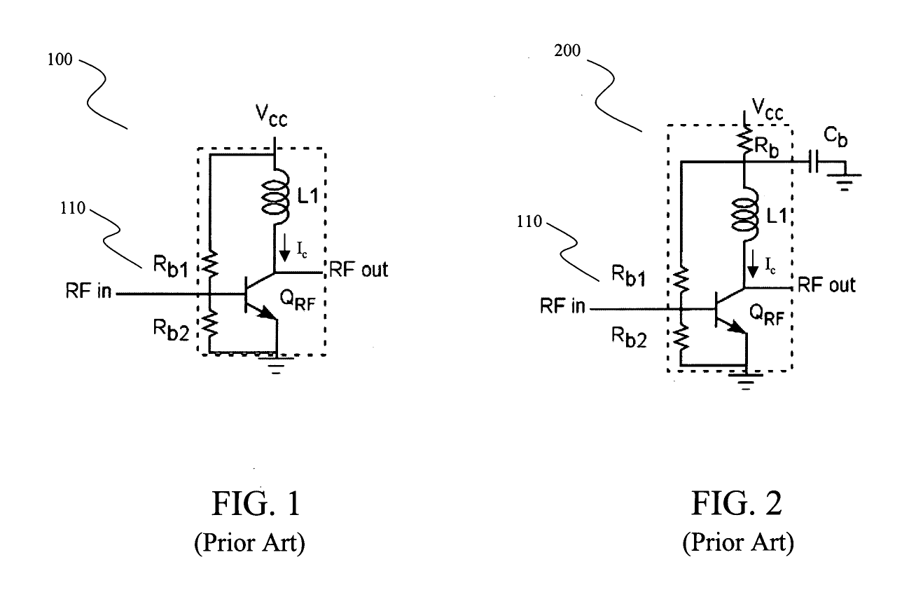

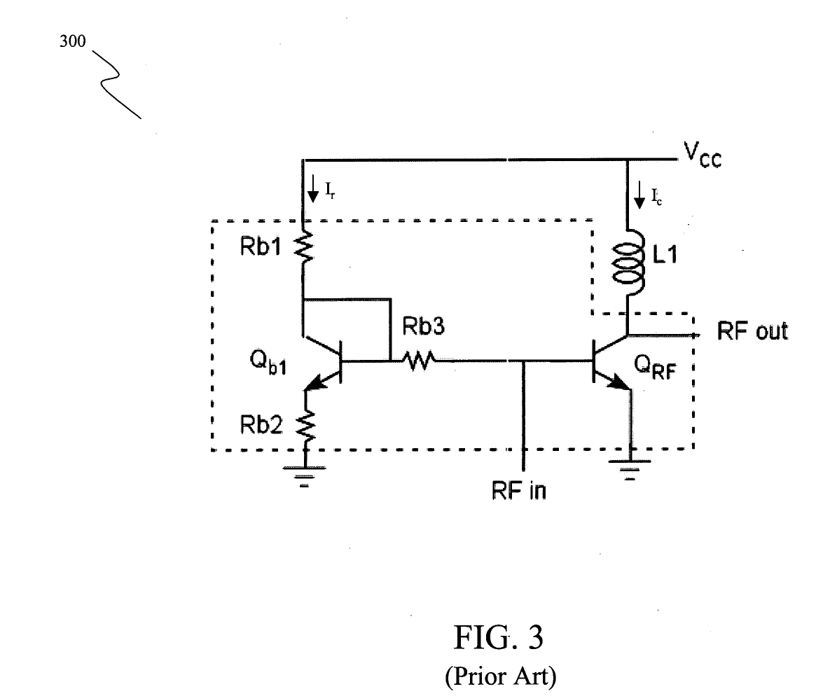

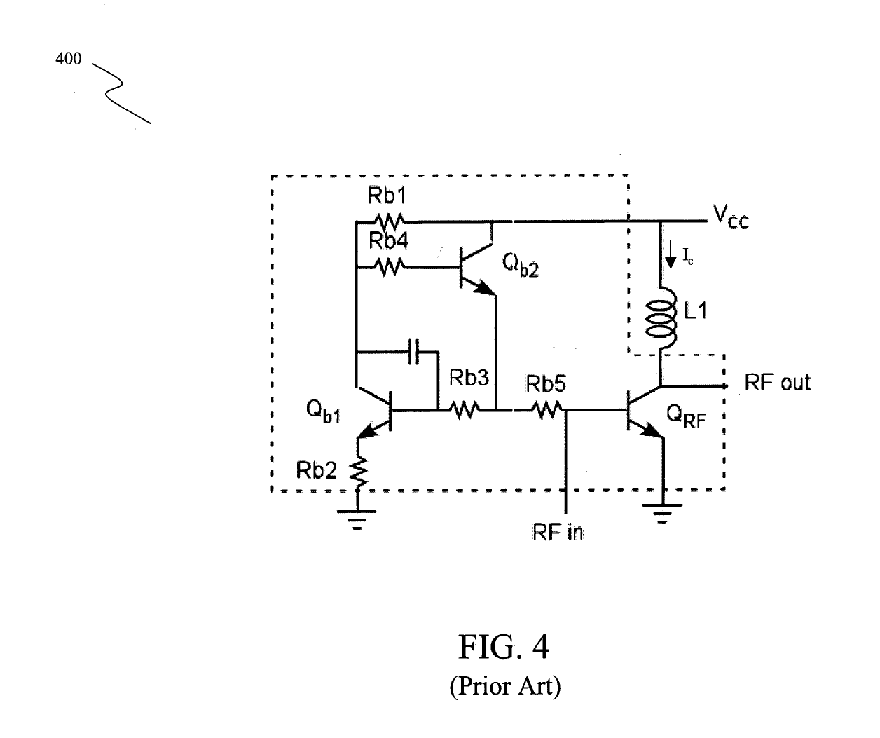

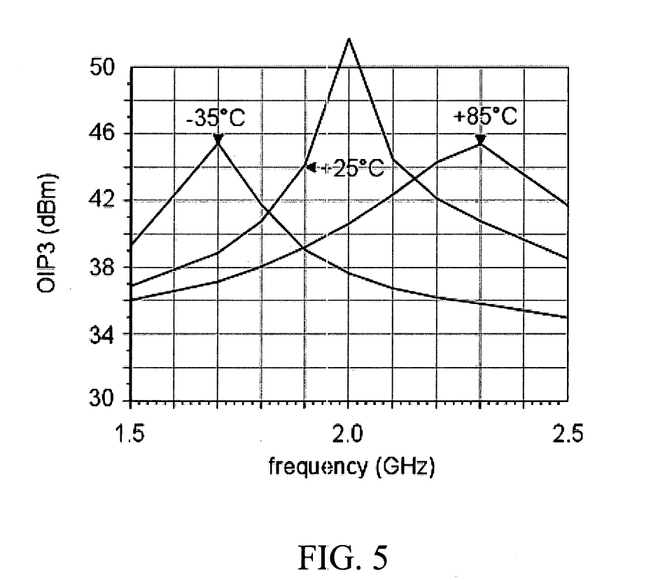

### DETAILED DESCRIPTION OF THE INVENTION

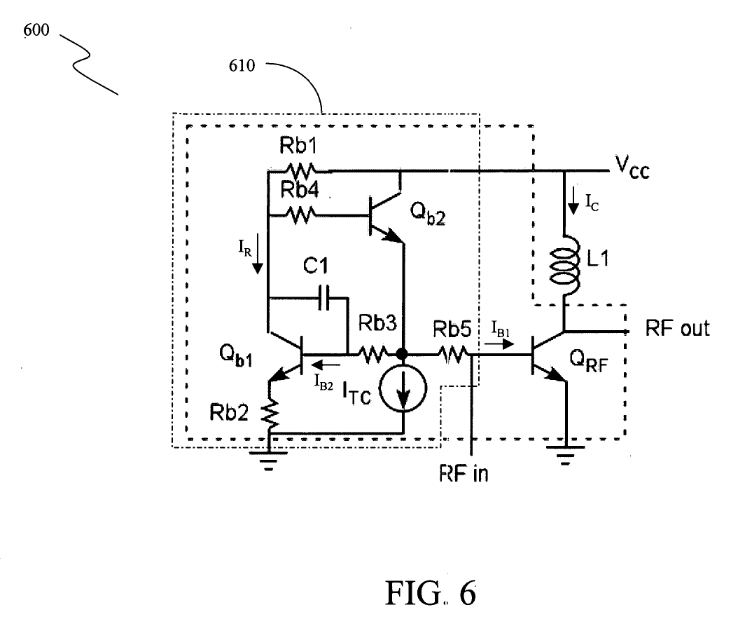

The operation of an amplifier circuit according to one embodiment of the present invention may be better understood with reference to FIG. 6. As shown in FIG. 6, the amplifier circuit 600 comprises a radio frequency (RF) bipolar junction transistor Q_{RF} having its base coupled to an input terminal “RF in” for receiving an RF input signal, its emitter coupled to ground, and its collector coupled to a power supply voltage V_{CC} and to a signal output terminal “RF out.” Circuit 600 may further comprise an inductor L1 coupled between the collector of transistor Q_{RF} and V_{CC}.

Circuit 600 further comprises a bias circuit 610 including a bias bipolar transistor Q_{b1}, buffer transistor Q_{b2}, first and second bias resistors R_{b1} and R_{b2}, first and second base resistors R_{b3} and R_{b5}, a resistor R_{b4}, and a temperature-compensated current source I_{TC}. Transistor Q_{b1} has its base coupled to the base of transistor Q_{RF} through first and second base resistors R_{b3} and R_{b5}, its collector coupled to V_{CC} through first bias resistor R_{b1}, and its emitter coupled to ground through second bias resistor R_{b2}. Transistor Q_{b2} has its base coupled to the collector of transistor Q_{b1} through resistor R_{b4}, its collector coupled to V_{CC}, and its emitter coupled to a circuit node between first and second base resistors R_{b3} and R_{b5}. Bias circuit 610 may further comprise a capacitor C1 coupled between the base and collector of transistor Q_{b1}. Current source I_{TC} is coupled to the circuit node between first and second base resistors R_{b3} and R_{b5}.

The RF input signal, which may typically be at a frequency in the range of a few hundred MHz to many GHz, is applied to the base of the RF transistor Q_{RF}. Generally, this connection will be DC-blocked using a capacitor or equivalent arrangement (not shown). In order for transistor Q_{RF} to provide reasonably linear amplification at high gain, a significant DC bias current I_{C} should flow through the transistor Q_{RF} and the inductor L1, if it is provided. The inductor L1, when provided, acts to isolate the supply voltage V_{CC} from variations in an RF current through transistor Q_{RF}. In one embodiment, transistors Q_{RF}, Q_{b1}, and Q_{b2}, resistors R_{b1}, R_{b2}, R_{b3}, R_{b4}, and R_{b5}, capacitor C1, and current source I_{TC} are part of an integrated circuit fabricated on a semiconductor substrate, as indicated by the dotted lines in FIG. 6. Inductor L1 can be external to the integrated circuit, or it can be an on-chip inductor formed on the same substrate as the integrated circuit.

An appropriate DC voltage to ensure proper bias current I_{C} is provided to the base of Q_{RF} through resistor R_{b5}, which acts to allow base current I_{B1} to flow to or from transistor Q_{RF} while partially isolating the remainder of the bias circuit 610 from the RF input signal. The resistance value of resistor R_{b5} is chosen to be small to avoid excessive DC voltage drop due to the flow of base current to or from transistor Q_{RF}. Additional isolation of the base of transistor Q_{b1} from the RF signal is provided by resistor R_{b3}. Capacitor C1 provides electrical stability and noise reduction in bias circuit 610. As a non-limiting example, resistor R_{b5} is about 20-100 ohms, resistor R_{b3} is about 100-1000 ohms, and capacitor C1 is about 1-3 pF. A reference current I_{R} through transistor Q_{b1} is set by resistors R_{b1} and R_{b2} in conjunction with the supply voltage V_{CC}. A base-emitter voltage of transistor Q_{b1} self-adjusts to accommodate the requisite reference current I_{R} through transistor Q_{b1}. Buffer transistor Q_{b2} provides a source for the base current I_{B1} for transistor Q_{RF} through R_{b5} and for a base current I_{B2} for transistor Q_{b1} through R_{b3}.

The RF input signal is also applied to the emitter of transistor Q_{b2} through resistor R_{b5}. Thus, a portion of the signal voltage appears across the base-emitter junction of transistor Q_{b2}. This junction acts as a nonlinear load conductance of approximately:

$$\begin{matrix}{σ}_{be} \approx \frac{ⅆ {I}_{e}}{ⅆ {V}_{be}} \\ = \frac{ⅆ}{ⅆ {V}_{be}} ( \frac{β + 1}{β} {I}_{c2} ) \\ \approx \frac{ⅆ {I}_{c2}}{ⅆ {V}_{be}} \\ = \frac{ⅆ}{ⅆ {V}_{be}} ( {I}_{S} {ⅇ}^{{qV}_{be} / kT} ) \\ = \frac{q}{kT} {I}_{S} {ⅇ}^{{qV}_{be} / kT} \\ = \frac{q}{kT} {I}_{c2}\end{matrix} \qquad ( 2 )$$

where σ_{be} is a base-emitter differential conductance associated with transistor Q_{b2}, Iₑ represents emitter current of transistor Q_{b2}, V_{be} is the base-emitter voltage of transistor Q_{b2}, β represents the beta value or current gain of transistor Q_{b2}, and I_{c2} represents collector current of transistor Q_{b2}.

The differential conductance σ_{be} is linearly dependent on the collector current I_{c2} of transistor Q_{b2}, and exponentially dependent on the RF voltage in V_{be}, as demonstrated by Eq. (2). The base-emitter junction capacitance of transistor Q_{b2} also varies with current, with an additional dependency on the frequency of the RF input signal. The nonlinear load associated with the buffer transistor Q_{b2} may cause a distortion in the RF input signal provided to transistor Q_{RF}, which, under certain conditions, could cancel the distortion caused by the RF transistor Q_{RF}, leading to improved linearity. Conditions under which the effect of the buffer transistor Q_{b2} can be beneficial needs to be established by detailed modeling or empirical investigation of the specific process and geometry under study. According to Eq. (2), a change in the current flowing in transistor Q_{b2} can change the nonlinear conductance σ_{be}. Furthermore, significant current can be drawn from the emitter of transistor Q_{b2} to change its collector current and therefore the conductance σ_{be} with little effect on the reference current through transistor Q_{b1} and thus on the bias current I_{C} of the RF transistor Q_{RF}.

In one embodiment of the present invention, current source I_{TC} is included in the bias circuit to draw current from the emitter of transistor Q_{b2}, in order to compensate for undesirable variations of predistortion with temperature. Therefore, any well-controlled temperature-varying current source may be used to construct I_{TC}, as long as the current source is fabricated in a manner that allows for tailored adjustments in the current-temperature relationship associated with the current source. Preferably, the current source I_{TC} should be able to operate relatively independently of variations in the power supply voltage and/or variations in component values caused by unintentional variations in either processes or materials used to fabricate the current source. The current-temperature relationship required to produce optimal amplifier linearity can be established empirically and/or by simulation for a given process and circuit design.

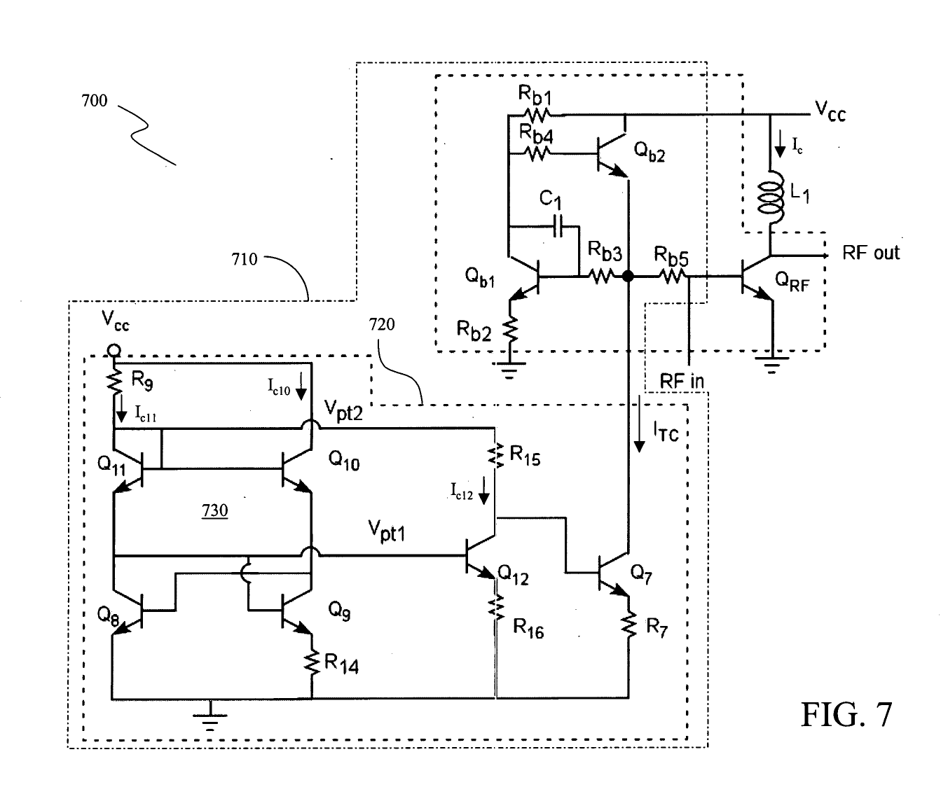

As one example of the current source I_{TC}, FIG. 7 illustrates an exemplary amplifier circuit 700 employing a temperature compensated predistortion bias circuit 710, which includes an I_{TC} current source 720. As shown in FIG. 7, I_{TC} current source 720 comprises transistors Q8, Q9, Q10, and Q11, which form a proportional-to absolute-temperature (PTAT) cell 730 for driving a mirror transistor Q12, which in turn controls a current source transistor Q7. I_{TC} current source 720 further comprises resistors R₇, R₉, R₁₄, R₁₅, and R₁₆. Transistors Q8 and Q11 are serially connected with each other and with resistor R₉ between V_{CC} and ground, and transistors Q9 and Q10 are serially connected with each other and with resistor R₁₄ between V_{CC} and ground. The base of transistor Q8 is coupled to the collector of transistor Q9, and the base of transistor Q9 is coupled to the collector of transistor Q8. Transistor Q12 has its base coupled to the base of transistor Q9 and to the collector of transistor Q8, its emitter coupled to the ground through resistor R₁₄, and its collector coupled to the collector of transistor Q11, which, together with the emitter of transistor Q11, is coupled to V_{CC} though transistor R₉. The emitter of transistor Q9 is coupled to the ground through resistor R₁₄. Transistor Q7 has its collector coupled to a circuit node between resistors R_{b5} and R_{b3}, its base coupled to the collector of transistor Q12, and its emitter coupled to the ground through resistor R₇.

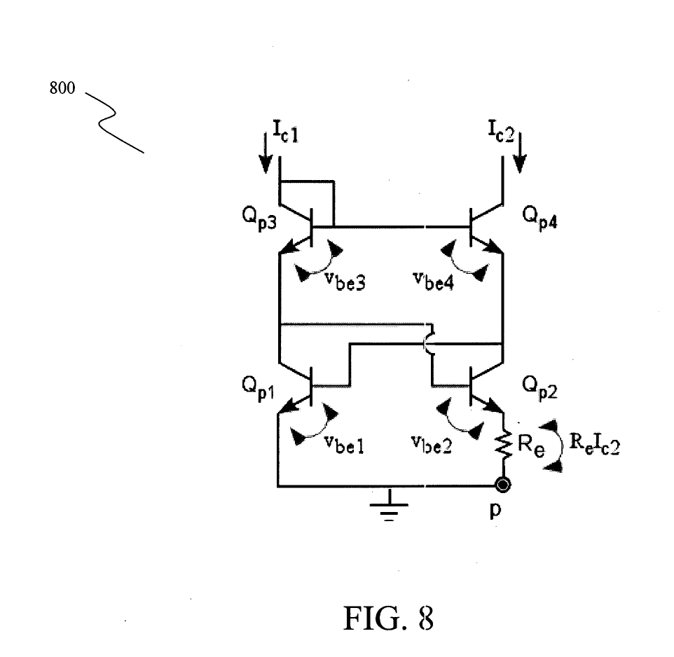

The operation of the PTAT cell 730 may be better understood by reference to FIG. 8, which shows a PTAT cell 800 formed of four transistors Qₚ₁, Qₚ₂, Qₚ₃, and Qₚ₄, and a resistor Rₑ, in a configuration similar to that of PTAT cell 730, with transistor Qₚ₁, Qₚ₂, Qₚ₃, and Qₚ₄ and resistor Rₑ in PTAT cell 800 in similar positions as those of transistors Q8, Q9, Q11, and Q10 and resistor R₁₄ in PTAT cell 730, respectively. Consider a loop from a circuit node P in PTAT cell 800, as shown in FIG. 8, to the base of transistor Qₚ₁ across the base-emitter junction of transistor Qₚ₁, from there to the base of transistor Qₚ₄ across the base-emitter junction of transistor Qₚ₄, from there to the emitter of transistor Qₚ₃ across the base-emitter junction of transistor Qₚ₃, from there to the emitter of transistor Qₚ₂ across the base-emitter junction of transistor Qₚ₂, and from there back to the circuit node P after passing through resistor Rₑ. General circuit theory dictates that the sum of voltages along this loop must be zero. Therefore:
V_{be1}+V_{be4}−V_{be3}−V_{be2}−I_{c2}Rₑ=0 (3)
where V_{be1}, V_{be4}, V_{be3}, and V_{be2} are base-emitter voltages of transistors Qₚ₁, Qₚ₄. Qₚ₃, and Qₚ₂, respectively, and I_{c2} is a current through transistors Qₚ₂ and Qₚ₄, neglecting the base currents.

The voltage across each base-emitter junction has a logarithmic relation with the current flow through it due to the exponential current-voltage characteristic of the associated transistor operating in the forward active region. Let the saturation currents of transistors Qₚ₁, Qₚ₂, Qₚ₃, and Qₚ₄ be I_{S1}, I_{S2}, I_{S3}, and I_{S4}, respectively, neglecting base currents, and using Eq. (1), Eq. (3) becomes:

$${V}_{T} ln ( \frac{{I}_{c1}}{{I}_{S1}} ) + {V}_{T} ln ( \frac{{I}_{c2}}{{I}_{S4}} ) - {V}_{T} ln ( \frac{{I}_{c1}}{{I}_{S3}} ) - {V}_{T} ln ( \frac{{I}_{c2}}{{I}_{S2}} ) - {I}_{c2} {R}_{e} = 0 \qquad ( 4 )$$

where I_{c1} is the current through transistors Qₚ₁ and Qₚ₃, and V_{T}=kT/q is defined as the thermal voltage.

Solving Eq. (4) for I_{c2} results:

$${I}_{c2} = \frac{{V}_{T}}{{R}_{e}} ln ( \frac{{I}_{c1} {I}_{c2} {I}_{S3} {I}_{S2}}{{I}_{S1} {I}_{S4} {I}_{c1} {I}_{c2}} ) = \frac{{V}_{T}}{{R}_{e}} ln ( \frac{{I}_{S3} {I}_{S2}}{{I}_{S1} {I}_{S4}} ) . \qquad ( 5 )$$

Presuming that transistors Qₚ₁, Qₚ₂, Qₚ₃, and Qₚ₄ are fabricated on a same semiconductor substrate using a same set fabrication process, their saturation currents should be very accurately proportional to the respective junction areas. Let the ratio of base-emitter junction areas of transistors Qₚ₂, Qₚ₃, and Qₚ₄ to that of transistor Qₚ₁ be A_{S2}, A_{S3}, and A_{S4}, respectively, I_{c2} becomes:

$${I}_{c2} = \frac{{V}_{T}}{{R}_{e}} ln ( \frac{{A}_{S3} {I}_{S1}}{{I}_{S1}} \frac{{A}_{S2} {I}_{S1}}{{A}_{S4} {I}_{S1}} ) = \frac{{V}_{T}}{{R}_{e}} ln ( \frac{{A}_{S3} {A}_{S2}}{{A}_{S4}} ) . \qquad ( 6 )$$

Therefore, from Eq. (6), it is observed that the collector current I_{c2} depends only on the junction area ratios A_{S2}, A_{S3}, and A_{S4} associated with transistors Qₚ₁, Qₚ₂, Qₚ₃, and Qₚ₄ and the resistor value chosen for resistor Rₑ, and not on the absolute magnitude of the saturation currents I_{S1}, I_{S2}, I_{S3}, and I_{S4}. Note that I_{c2} is linearly proportional to the absolute temperature through the thermal voltage V_{T}, as the name of the PTAT cell indicates. Thus, for example, if the base-emitter junction area of Qₚ₂ is chosen to be 4 times that of Qₚ₁, the base-emitter junction area of Qₚ₃ twice that of Qₚ₁, and the base-emitter junction area of Qₚ₄ the same as that of Qₚ₁, I_{c2} becomes:

$${I}_{c2} = \frac{{V}_{T}}{{R}_{e}} ln ( \frac{2 \cdot 4}{1} ) = \frac{{V}_{T}}{{R}_{e}} ln ( 8 ) \qquad ( 7 )$$

Referring back to FIG. 7, in a non-limiting example, the base-emitter junction areas of transistors Q8 and Q10 are equal, and the base-emitter junction areas of transistors Q9 and Q11 are equal to each other but twice as large as those of transistors Q8 and Q10, it can be shown that the current through the collector of transistor Q10 is approximately:

$${I}_{c10} = \frac{{V}_{T}}{{R}_{e}} ln ( \frac{2 \cdot 2}{1} ) = \frac{{V}_{T}}{{R}_{e}} ln ( 4 ) \qquad ( 8 )$$

Thus, neglecting the base currents, the current through transistors Q9 and Q10 is linearly proportional to temperature through V_{T} and nearly independent of supply voltage. It can also be shown that the voltage at the collector of transistor Q11 is nearly independent of small variations in the supply voltage. Because the collector current I_{c10} is constant with respect to variations in the supply voltage V_{CC}, the base-emitter voltage V_{be10} of transistor Q10 is essentially constant. Thus, any variation δv₁₁ in the voltage V₁₁ at the collector of transistor Q11 is immediately mirrored to the emitter of transistor Q10, which is connected to the collector of transistor Q14 and to the base of transistor Q8. Treating transistor Q8 as a transconductance amplifier, the change δI₁₁ in the collector current I_{c11} of transistor Q11 due to this change in voltage is gₘ₈δv₁₁, where gₘ₈ represents the transconductance associated with transistor Q8. This change in current flows in series through transistor Q11 and resistor R₉. Thus, for a change δv_{cc} in supply voltage V_{CC}, the corresponding change δv₁₁ in the voltage V₁₁ at the collector of transistor Q11 can be solved as in the following.

$$\begin{matrix}δ {v}_{11} = δ {v}_{cc} - {R}_{9} ( δ {I}_{11} ) = δ {v}_{cc} - {R}_{9} ( {g}_{m11} δ {v}_{11} ) \\ δ {v}_{11} ( 1 + {R}_{9} {g}_{m11} ) = δ {v}_{cc} \\ δ {v}_{11} = \frac{δ {v}_{cc}}{1 + {R}_{9} {g}_{m11}} << δ {v}_{cc}\end{matrix} \qquad ( 9 )$$

As a non-limiting example, if R₉ is approximately 1000 ohms, I_{C11} is approximately 2 mA, and transconductance gₘ₈ is about (40)(2)=80 mS at room temperature so R₉gm₁₁ is roughly (0.08)(1000)=80, any change δv_{CC} in supply voltage V_{CC} would be attenuated almost 100-fold at collector of transistor Q11. Thus, the voltage output from the collector of transistor Q12 and the operation of the current source 720 are substantially independent of supply voltage over a wide range.

If the resistance value of resistor R₁₆ is set to be equal to that resistor R₁₄, the collector current of transistor Q12 would mirror that of transistor Q9 provided the transistors have the same or nearly the same configuration. If the resistors differ in value, to a first approximation, the current through Q12 scales inversely as the ratio of R₁₆/R₁₄ assuming the base-emitter voltage V_{be12} of transistor Q12 remains approximately the same (since the current through a transistor has an exponential relationship with the base-emitter voltage). As a non-limiting example, R14 is set to be approximately 20 ohms and R16 is set to be approximately 100 ohms, so that the collector current of transistor Q12 is nearly proportional to the absolute temperature but the dependency is much less than that of transistor Q9, as numerical solution of related transcendental equations shows that the current I_{c12} through transistor Q12 would be about equal to the current I_{c9} through transistor Q9 divided by 3.4, i.e., I_{c12}=I_{c9}/3.4. This current I_{c12} is then multiplied by the resistance value associated with resistor R₁₅ to produce a voltage that is inversely proportional to temperature and is used to drive the base of transistor Q7. The resulting voltage impressed across resistor R7 through the base-emitter diode of transistor Q7 produces a compensation current I_{TC}, which is inversely proportional to temperature.

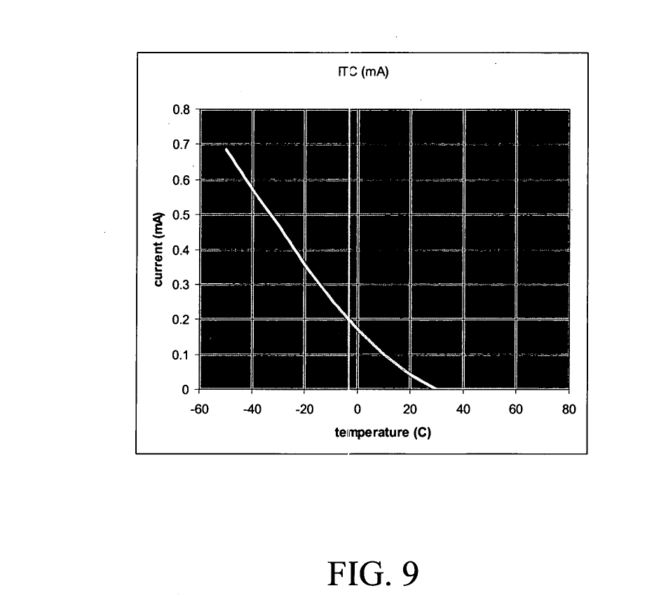

Adjustment of the two resistors R16 and R15 allows considerable freedom to vary both the magnitude of the compensation current I_{TC} as well as its degree of dependency on temperature. In a non-limiting example, a 2-μm indium gallium phosphide based heterojunction bipolar transistor (InGaP HBT) process is used to fabricate the amplifier circuit 700, and it is empirically found that the injected current I_{TC} should optimally be negligible for temperatures greater than room temperature, and increase approximately linearly as temperature is decreased. The correct characteristic is achieved by setting R₁₅ to be approximately 2900 ohms. The resulting current-temperature characteristic for I_{TC} is depicted in FIG. 9. In this example, the RF transistor Q_{RF} is a InGaP HBT having an emitter area of about 420 μm². For different design of the bias circuit 710 and associated passive components, as shown in FIG. 7, and for different processes for fabricating circuit 700, a different optimal relationship of injected current I_{TC} vs. temperature T may be appropriate. In most cases the desired injected current characteristic can be obtained from the above example after appropriate variations in the resistors R7, R15, and R16.

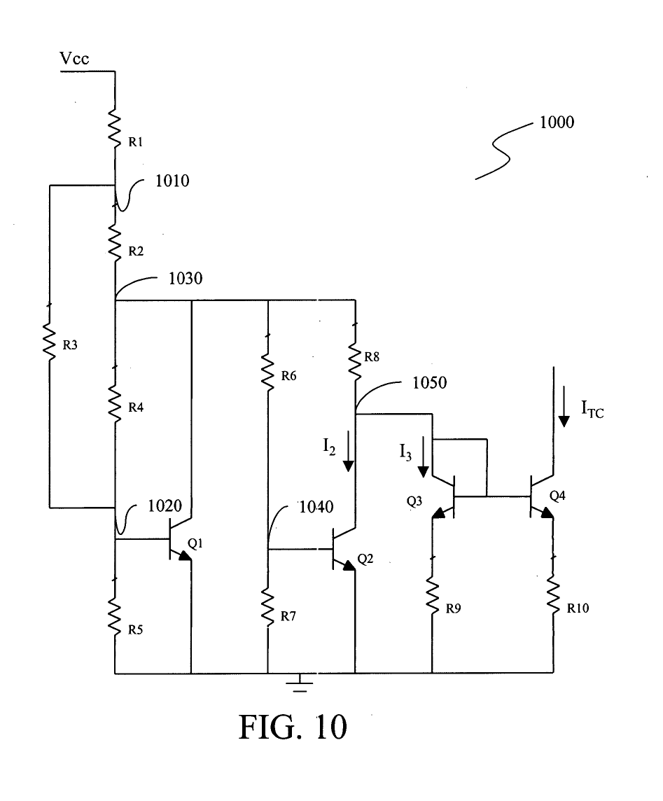

The I_{TC} current source 720 in FIG. 7 is just one example of implementing the current source I_{TC} in FIG. 6. As another example, FIG. 10 illustrates a negative temperature coefficient current source 1000, which may also be used as the I_{TC} current source in FIG. 6. As shown in FIG. 10, current source 1000 comprises resistors R₁, R2, R4, and R5 serially coupled with each other between V_{CC} and ground, a resistor R3 coupled between a circuit node 1010 between resistor R1 and R2 and a circuit node 1020 between resistors R4 and R5, a first transistor Q1 having its base coupled to circuit node 1020, its collector coupled to a circuit node 1030 between resistors R2 and R4, and its emitter coupled to ground, resistors R6 and R7 serially coupled with each other between circuit node 1030 and ground, and a second transistor Q2 having its base coupled to a circuit node 1040 between resistors R6 and R7, its collector coupled to circuit node 1030 through a resistor R8, and its emitter coupled to ground. Current source 1000 further comprises a third resistor Q3 having its base and collector tied with each other and coupled to a circuit node 1050 between resistor R8 and transistor Q2, and a fourth transistor Q4 coupled to the third transistor in a current mirror arrangement. The emitter of transistor Q3 is coupled to ground through a resistor R9, and the emitter of transistor Q4 is coupled to ground through a resistor R10.

Resistors R1, R2, R3, R4, and R5 and transistor Q1 act as a voltage regulator such that the voltage at circuit node 1030 is stable through variations in the V_{CC}. A positive temperature coefficient current I₂ is generated through transistor Q2, which current goes up with increased temperature. As a result, the voltage at circuit node 1050, i.e., the collector of transistor Q2, goes down with increased temperature, and so does the current I₃ through transistor Q3. The current I₃ is mirrored and scaled in transistor Q4 to result in the I_{TC} current through transistor Q4 to be a negative temperature coefficient current that decreases with increased temperature. The current I_{TC} is injected into the buffer transistor Q_{b2} in FIG. 6 to adjust the extent of predistortion created by the buffer transistor and to compensate for effects caused by variations in temperature. Current I_{TC} and its dependency on temperature in FIG. 10 can be adjusted by adjusting the resistance values associated with resistors R8, R9, and R10.

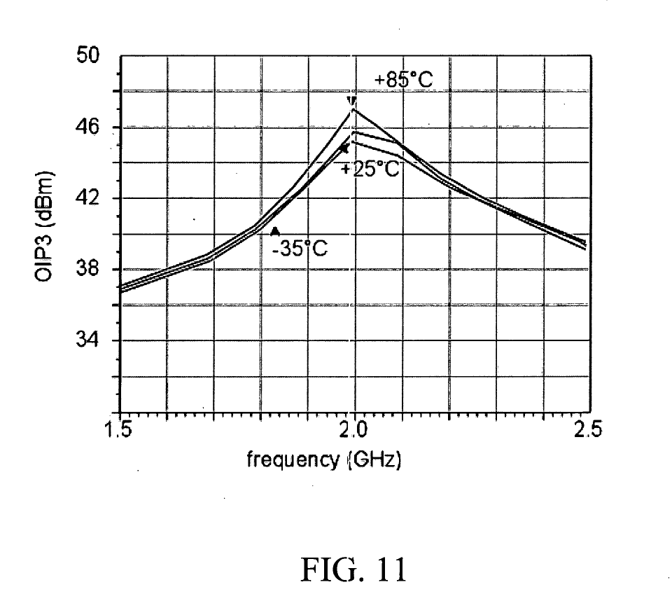

The simulated OIP3 performance of an example of amplifier circuit 600 using an I_{TC} current source similar to that depicted in FIG. 10 is plotted in FIG. 11. As shown in FIG. 11, the frequency at which an optimal overall linearity performance of amplifier circuit 600 is obtained is fairly independent of temperature. The presence of the I_{TC} current source produces a temperature-dependent variation in the phase and amplitude of the predistortion frequency products generated by the non-linear characteristics of the base-emitter junction of the buffer transistor Q_{b2}. These predistortion products in turn cancel out distortion frequency products generated in the amplifier transistor Q_{RF}, resulting in a temperature-independent overall amplifier linearity enhancement. Furthermore, because of the design of the current source I_{TC}, these results are relatively independent of variations in the supply voltage V_{CC}, and of variations of the absolute resistance values of the resistors in the current source, as long as the ratios of the resistance values are maintained.

This invention has been described in terms of a number of embodiments, but this description is not meant to limit the scope of the invention. Numerous variations will be apparent to those with skill in the art, without departing from the spirit of the invention disclosed herein.

1. An amplifier bias circuit for use with an amplifier transistor receiving an input signal, comprising:
a current buffer configured to provide DC bias control of the amplifier transistor and to improve linearity of the amplifier transistor by creating a predistortion of the input signal; and
a current source configured to generate a current for injection into the current buffer to adjust the extent of predistortion and to compensate for effects caused by variations in ambient conditions.

2. The amplifier bias circuit of claim 1, further comprising a bias transistor coupled with the amplifier transistor in a current mirror arrangement.

3. The amplifier bias circuit of claim 2, wherein the current buffer is configured to provide DC bias control of the amplifier transistor by producing a first base current for the bias transistor and a second base current for the amplifier transistor.

4. The amplifier bias circuit of claim 2, wherein a first base of the bias transistor is coupled to a second base of the amplifier transistor through first and second resistors, and a terminal of the buffer transistor is coupled to a circuit node between the first and second resistor.

5. The amplifier bias circuit of claim 4, wherein the first resistor is coupled to the first base and the second resistor is coupled to the second base, a resistance value of the first resistor being substantially larger than that of the second resistor.

6. The amplifier bias circuit of claim 1, wherein the current generated by the current source increases with decreasing ambient temperature.

7. The amplifier bias circuit of claim 1, wherein the current source comprises a proportional-to-absolute-temperature (PTAT) cell.

8. The amplifier bias circuit of claim 7, wherein the current source further comprises a mirror transistor and a current source transistor, the PTAT cell driving the mirror transistor and the mirror transistor controlling the current source transistor.

9. The amplifier bias circuit of claim 1, wherein the current source comprises a plurality of resistors, and wherein the current generated by the current source depends on ratios of the resistance values associated with the plurality of resistors.

10. The amplifier bias circuit of claim 9, wherein the current generated by the current source has a dependency on temperature, and a degree of the dependency can be changed by changing ratios of the resistance values associated with the plurality of resistors.

11. An amplifier circuit, comprising:
an amplifier transistor configured to amplify an input signal received at a terminal of the amplifier transistor;
a bias transistor forming a current mirror with the amplifier transistor for stabilizing a bias operating point for the amplifier transistor;
a buffer transistor coupled to the bias transistor and to the amplifier transistor, and configured to provide base currents to the amplifier transistor and the bias transistor; and
a current source coupled to the buffer transistor and configured to generate a temperature dependent current for injection into the buffer transistor.

12. The amplifier circuit of claim 11, wherein the buffer transistor is configured to create a predistortion of the input signal that cancels a distortion generated by the amplifier transistor.

13. The amplifier circuit of claim 11, wherein the current source is configured to generate a temperature dependent current that adjusts the predistortion created by the buffer transistor.

14. The amplifier circuit of claim 11, further comprising a first resistor coupled to the bias transistor and a second resistor coupled to the first resistor and to the amplifier transistor, a resistance value of the first resistor being substantially larger than that of the second resistor.

15. The amplifier circuit of claim 11, wherein the current generated by the current source increases with decreasing ambient temperature.

16. The amplifier circuit of claim 11, wherein the current source comprises a proportional-to-absolute-temperature (PTAT) cell.

17. The amplifier circuit of claim 16, wherein the current source further comprises a mirror transistor and a current source transistor, the PTAT cell driving the mirror transistor and the mirror transistor controlling the current source transistor.

18. The amplifier circuit of claim 11, wherein the current source comprises a plurality of resistors, and wherein the current generated by the current source depends on ratios of the resistance values associated with the plurality of resistors.

19. The amplifier circuit of claim 18, wherein the current generated by the current source has a dependency on temperature, and a degree of the dependency can be changed by changing ratios of the resistance values associated with the plurality of resistors.

20. A method for improving a linearity of an amplifier circuit including an amplifier transistor, comprising:
generating a reference current through a bias transistor coupled to the amplifier transistor in a current mirror arrangement;
generating first and second base currents using a buffer transistor coupled to the bias and amplifier transistors, the first base current being provided to the bias transistor and the second base current being provided to the amplifier transistor; and
generating a temperature-dependent current for injection into the buffer transistor to adjust a differential conductance associated with the buffer transistor.
